(19) United States
(12) Patent Application Publication
(10) Pub. No.: US 2024/0143282 A1
(43) Pub. Date: May 2, 2024

(54) HARDWARE ACCELERATION FOR PIPELINED VECTOR OPERATIONS

(71) Applicant: Texas Instruments Incorporated, Dallas, TX (US)

(72) Inventors: Mathews John, Bangalore (IN); Jawaharlal Tangudu, Bangalore (IN); Pankaj Gaur, Bangalore (IN); Divyansh Jain, Bangalore (IN); Pankaj Gupta, Bangalore (IN)

(21) Appl. No.: 17/977,813

(22) Filed: Oct. 31, 2022

(51) Int. Cl. G06F 7/57; G06F 17/16

(52) U.S. Cl. CPC G06F 7/57; G06F 17/16

(57) ABSTRACT

In described examples, an integrated circuit includes an output terminal coupled to an input of a power amplifier, a feedback terminal coupled to an output of the power amplifier, a data terminal that receives a data stream, and a digital pre-distortion (DPD) circuit. The DPD circuit includes a capture circuit, a DPD estimator responsive to the data stream and the feedback terminal, and a DPD corrector responsive to the DPD estimator. The DPD estimator includes an instruction memory configured to store instructions and a vector arithmetic processing unit (APU) coupled to the instruction memory. The vector APU includes vector memories, vector arithmetic blocks, and an instruction decode block. The vector arithmetic blocks include vector addition blocks and vector multiplication blocks. The instruction decode block is configured to cause the vector APU to perform complex domain vector arithmetic on vectors stored in the vector memories in response to the instructions.

### TECHNICAL FIELD

This application relates generally to pipelined vector operations, and more particularly to hardware acceleration for pipelined vector operations on complex vectors.

### BACKGROUND

Various applications use vector operations performed on vectors with hundreds of elements or matrices with hundreds of elements in constituent vectors. For example, convolution layers of neural networks can be processed using vector operations on feature maps windowed by filter kernels to form corresponding matrices comprised of large vectors. Also, certain models for performing digital pre-distortion (DPD), which is used to compensate for power amplifier nonlinearity in wireless base stations, solve for equations with large numbers of coefficients using vector arithmetic applied to large vectors formed using the coefficients. Accordingly, improving efficiency of vector operation control, and corresponding memory access and arithmetic, can be used to improve system efficiency and response rate.

### SUMMARY

In described examples, an integrated circuit includes an output terminal coupled to an input of a power amplifier, a feedback terminal coupled to an output of the power amplifier, a data terminal that receives a data stream, and a digital pre-distortion (DPD) circuit. The DPD circuit includes a capture circuit, a DPD estimator responsive to the data stream and the feedback terminal, and a DPD corrector responsive to the DPD estimator. The DPD estimator includes an instruction memory configured to store instructions and a vector arithmetic processing unit (APU) coupled to the instruction memory. The vector APU includes vector memories, vector arithmetic blocks, and an instruction decode block. The vector arithmetic blocks include vector addition blocks and vector multiplication blocks. The instruction decode block is configured to cause the vector APU to perform complex domain vector arithmetic on vectors stored in the vector memories in response to the instructions.

### BRIEF DESCRIPTION OF THE DRAWINGS

FIG. 1 shows a functional block diagram of an example wireless base station.

FIG. 2 is a functional block diagram of an example estimation subsystem.

FIG. 3 shows a process diagram of an example conjugate gradient method.

FIG. 4 shows a functional block diagram of an example DPD estimator and DPD corrector.

FIG. 5 shows a bitwise format of an example instruction for the CG accelerator of FIG. 4.

FIG. 6 shows a functional block diagram of an example of the arithmetic blocks of FIG. 4.

FIG. 7 shows a diagram of an example division process of the divider of FIG. 6.

FIG. 8A shows a functional block diagram of the real part block as shown in FIG. 6.

FIG. 8B shows a diagram of an example addition process of adder-1 of FIG. 6.

FIG. 8C shows a functional block diagram of an example pipeline of adder-1 of FIGS. 6 and 8.

FIG. 9A shows a timing diagram illustrating example signal timing of the real part block of FIG. 6.

FIG. 9B shows a timing diagram illustrating example signal timing of the real part block of FIG. 6, including additional detail relating to partial accumulation.

FIG. 9C shows a timing diagram illustrating example signal timing of the real part block of FIG. 6, including additional detail relating to a final accumulation phase.

FIG. 10A shows an example of a Hermitian matrix as stored in the matrix memory of FIGS. 2 and 4.

FIG. 10B illustrates an example data layout of the matrix memory of FIGS. 2 and 4.

FIG. 10C illustrates an example data layout of the matrix memory of FIGS. 2 and 4.

The same reference numerals or other reference designators are used in the drawings to designate the same or similar (functionally and/or structurally) features.

### DETAILED DESCRIPTION

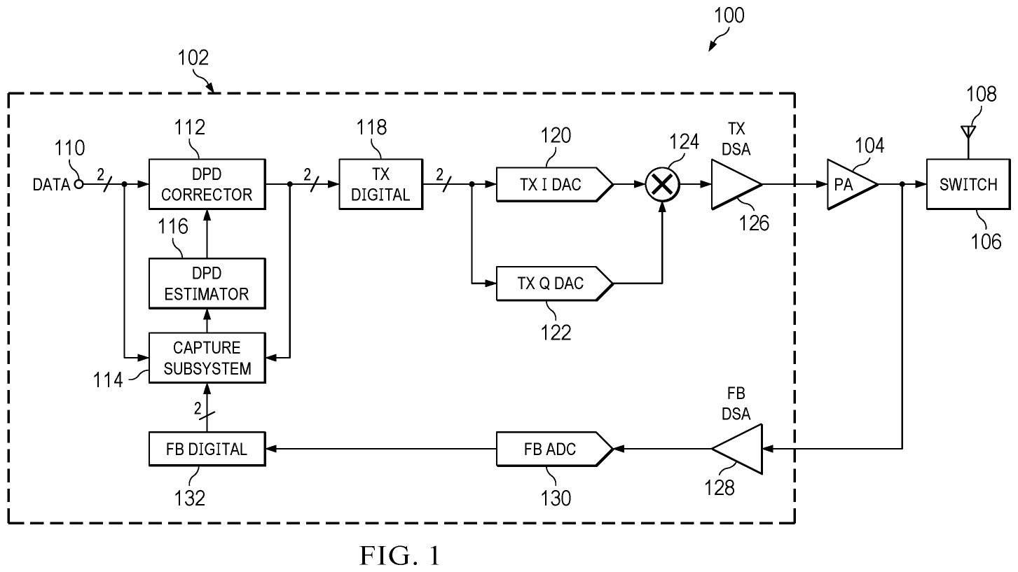

FIG. 1 shows functional block diagram of an example wireless base station 100. The wireless base station 100 includes a signal generator 102, a power amplifier (PA) 104, a switch/diplexer 106, and an antenna 108. The signal generator 102 includes a data terminal 110 adapted to receive a data signal (DATA) that includes an in-phase (I) component and a quadrature (Q) component, a DPD corrector 112, a capture subsystem 114, a DPD estimator 116, a transmitter (Tx) digital block 118, a Tx I digital-to-analog converter (DAC) 120, a Tx Q DAC 122, a complex mixer 124, a Tx digital step attenuator (DSA) 126, a feedback (FB) DSA 128, a FB analog-to-digital converter (ADC) 130, and a FB digital block 132. As further described below, the complex mixer 124 includes a cosine mixer and a sine mixer (not separately shown), and adds together the outputs of the cosine and sine mixers to produce a mixer output. In FIG. 1, marks indicating that a connection includes two lines refer to the conveyance of an I signal portion (an I component or samples of the I component) and a Q signal portion (a Q component or samples of the Q component) on respective separate lines.

In some examples, the power amplifier 104 of the wireless base station 100 is operated in a highly nonlinear region to improve efficiency. This results in increased adjacent channel leakage ratio (ACLR) and error vector magnitude (EVM), potentially violating design requirements. ACLR measures relative power at specified frequency offsets from an assigned channel of a signal transmitted by the wireless base station 100 with respect to the power transmitted within the assigned channel. EVM measures deviation of amplitudes and phase shifts of symbols transmitted by the wireless base station 100 from ideal constellation points. Accordingly, ACLR measures signal leakage outside an assigned frequency band, and EVM measures in-band signal quality loss. Increased ACLR or EVM makes it less likely that a receiver will properly decode a received signal.

DPD is a technique used to compensate for nonlinearities introduced by the power amplifier 104 by pre-distorting an input baseband signal, such as the DATA signal received by the DPD corrector 112. Nonlinearity of the power amplifier 104 can be described as a function f(x). The DPD corrector 112 applies an inverse function of f(x), f⁻¹(x), to the DATA signal, so that ideally, the power amplifier 104 outputs a signal that can be converted back into baseband to produce f(f⁻¹(DATA))=DATA. That is, the DPD corrector 112 distorts the DATA signal in a manner designed to cause the distortions introduced by the power amplifier 104 to produce a corrected signal.

The data terminal 110 (which may receive data from a processor or other circuitry or from a wired network connected to terminal 110, for example) is connected to a first input of the DPD corrector 112 and a first input of the capture subsystem 114. The FB digital block 132 outputs a baseband feedback signal to a second input of the capture subsystem 114. The DPD corrector 112 samples the I and Q components of the DATA signal, applies pre-distortion to the DATA signal samples using a pre-distortion model generated by the DPD estimator 116, and outputs the pre-distorted samples to a third input of the capture subsystem 114 and an input of the Tx digital block 118. The capture subsystem 114 samples the DATA signal and the baseband feedback signal and provides resulting samples to an input of the DPD estimator 116. The DPD estimator 116 uses these samples to generate the pre-distortion model, which it provides to a second input of the DPD corrector 112.

The TX digital block 118 interpolates samples of the DATA signal received from the DPD corrector 112 to convert a relatively low sample rate to a relatively high sample rate. The TX digital block 118 outputs an I component portion of the resulting samples to the Tx I DAC 120 and outputs a Q component portion of the resulting samples to the Tx Q DAC 122. The Tx I DAC 120 converts the I component samples received from the TX digital block 118 to an analog I component signal, and. The Tx Q DAC 122 converts Q component samples received from the TX digital block 118 to an analog Q component signal. The Tx I DAC 120 and the Tx Q DAC 122 output respective I and Q components to the complex mixer 124.

The mixer 124 multiplies the I signal component by the cosine of a carrier wave, multiplies the Q signal component by the sine of the carrier wave, phase shifting the Q component by 90° with respect to the I component, and adds the multiplied I and Q components together to generate a mixed signal. The mixer 124 provides the resulting mixed signal to the Tx DSA 126. The Tx DSA 126 amplifies/attenuates the mixed signal and outputs the amplified/attenuated signal to the power amplifier 104. The power amplifier 104 outputs to the switch 106 and to the FB DSA 128. The switch 106 connects the power amplifier 104 to and disconnects the power amplifier 104 from the antenna 108 (such as in a time division duplexing (TDD) system, in which the antenna 108 is disconnected from a transmitter that includes the power amplifier 104 during receiving time slots).

The FB DSA 128 steps down the gain of the feedback signal to match an amplitude regime of the DATA signal, and outputs to the FB ADC 130. The FB ADC 130 converts the analog feedback signal into a digital signal, and provides the result to an input of the FB digital block 132. The FB digital block 132 mixes down the RF signal output by the power amplifier 104 to baseband, and produces separate I and Q (real and imaginary) signal components. As described above, the FB digital block 132 provides the resulting baseband feedback signal, including the I and Q signal components, to the capture subsystem 114 to enable generation of the pre-distortion model by the DPD estimator 116 and production of a pre-distorted signal by the DPD corrector 112. Accordingly, the FB DSA 128, FB ADC 130, and FB digital block 132 together mix the output of the power amplifier 104 back to baseband for comparison to the DATA signal and further DPD refinement based on a differential from the comparison.

In some examples, nonlinearities introduced by the power amplifier 104 include not only nonlinearities applied to a signal in isolation, but also memory effects—nonlinearities that are dependent on signals previously processed by the power amplifier 104. For example, a power amplifier in steady state operation might ideally amplify a three to a six, but because of nonlinearity (and without memory effects), actually amplifies the three to a seven. However, because of memory effects, the power amplifier then amplifies the next signal portion, another three, to an eight. Pre-distortion models may include hundreds of variable terms to address these intricacies.

Generalized Memory Polynomial (GMP) is an example of a model used to perform pre-distortion. A GMP model can be represented as shown in Equation 1:

y(n)=G×x(n)+Σⱼ₌₁^{NCoeff}Cⱼ(l₁(j),l₂(j),p(D)×x(n−l₁(j))×|x(n−l₂(j))|^{p(j)} Equation 1

In Equation 1, y(n) is the output of the DPD corrector 112, G is gain, x(n) is the DATA signal, NCoeff is the number of coefficients C, Cⱼ is a coefficient of nonlinearity (including nonlinearities related to memory effects of the power amplifier 104), l₁ and l₂ are lag and lead values of the signal (delay values of the signal, acting as positive or negative offsets within the sample set for respective values of j), |x(n−l₂)| is the modulus of the delayed DATA signal, and p is the order of nonlinearity. The iterator j iterates through each available combination of l₁, l₂, and p; there are NCoeff such available combinations. In some examples, other or additional (or fewer) coefficients or other variables, measured or inferred values, scalars, or constants are included. In some examples, an alternative polynomial model type (or other model type amenable to solution using matrix arithmetic), such as dynamic deviation reduction (DDR), is used.

Ranges and values for terms such as l₁ and l₂, p, and NCoeff are determined in the lab, test environment, and/or manufacturing facility. In some examples, the set of terms used is determined in the lab, test environment, and/or manufacturing facility. In some examples, these determinations are made in response to the type of power amplifier 104 to be used. The DPD estimator 116 uses a large number of voltage data points sampled by the capture subsystem 114, such as 15,000 data points, to form a correspondingly large number of equations in the I-Q domain, which is a complex domain. The DPD estimator 116 solves for coefficients of the sample-derived equations, such as G and Cⱼ, during operation of the wireless base station 100. Because the equations are formed in a complex domain, corresponding coefficients are complex numbers. These complex numbers can also be expressed as an I (real) component and a Q (imaginary) component, or as a magnitude and a phase angle forming a vector in the complex domain. The DPD estimator 116 passes determined coefficients to the DPD corrector 112, which generates the pre-distorted signal using the DATA signal and the received coefficients. The DPD estimator 116 repeats the equation forming and coefficient determination process in response to temperature variations, continuously, periodically, or in response to other sensed ambient or signal-related changes. For example, a change in DATA signal profile from 200 MHz bandwidth to 250 MHz bandwidth can prompt a determination repetition.

In some examples, the DPD estimator 116 uses the conjugate gradient method to solve for sample-derived coefficients. Accordingly, a least squares aggregation algorithm can be used to reduce the problem to solving a matrix equation Ax=b. For example, the least squares aggregation method can be used to reduce the large number of equations (for example, 15,000 equations) corresponding to the samples received from the capture subsystem 114 to a smaller number of equations (for example, 500 equations). In some examples, the solution to the reduced equation set is known to give a best fit solution, in a least mean square sense, for the original, unreduced equation set.

In some examples, the least squares aggregation method is performed by multiplying a complex matrix that represents equations formed using the samples received from the capture subsystem by the conjugate transpose of that matrix, so that the resulting matrix is a square matrix with each dimension equal to the smaller number of equations. The elements of a complex matrix are complex numbers. In the conjugate transpose of a complex matrix H, H^{H}, an element (a+bi) in the i^{th} row and j^{th} column of H^{H} equals the complex conjugate (a−bi) of an element in the j^{th} row and i^{th} column of H.

A matrix H can be formed from samples of the DATA signal, and a matrix Z can be formed from samples of the feedback signal. For example, H can be a matrix sized as follows: number of equations (number of samples) times the number of coefficients per equation (NCoeff, or N). Matrix A equals H^{H}×H (or in some examples, H^{T}×H) and is an Hermitian matrix of size N×N, and matrix b equals H^{H}×Z (or in some examples, H^{T}×Z) and is a vector of size N×1. Matrix x contains the coefficients to be determined, and accordingly is a vector of size N×1. As described above, N is the total number of coefficients to determine.

An Hermitian matrix A is a complex square matrix equal to its own conjugate transpose, so that A=A^{H}. The complex conjugate of a complex number has the same sign for the real component, and the opposite sign for the imaginary component. For example, 5+3i is the complex conjugate of 5−3i. Because A is an Hermitian matrix, the DPD estimator 116 can store less than all elements of A, specifically elements in A including and above (or below) a row index equals column index diagonal of A.

The conjugate gradient method (CG) is iterative and of O(N³) complexity, and in some examples is computationally intensive, such as when N (the number of coefficients to determine) is large. In some examples, CG produces an exact solution after N steps. However, CG is sensitive to errors related to limited precision, high order non-linearity, and over-sampling of data. Further, in some examples, such as during system activation or when DATA signal profile changes, CG may require multiple iterations to converge to an accurate solution.

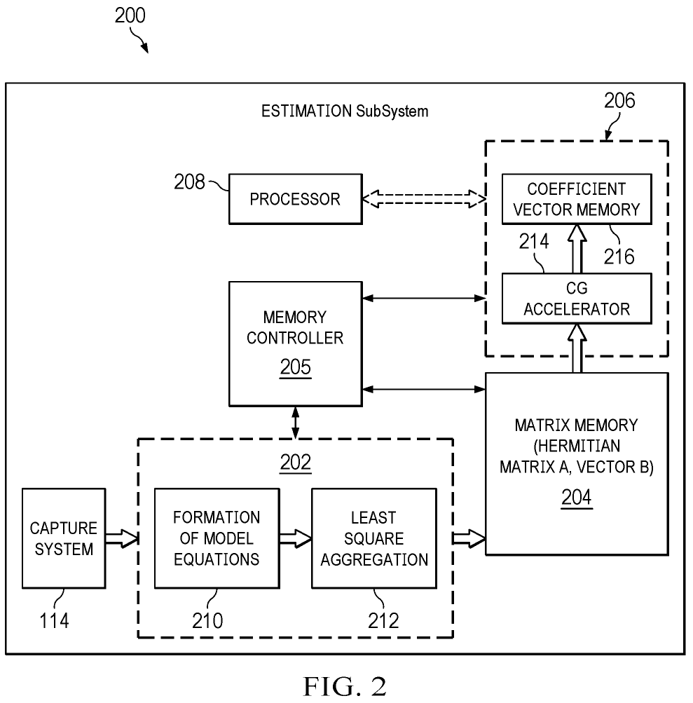

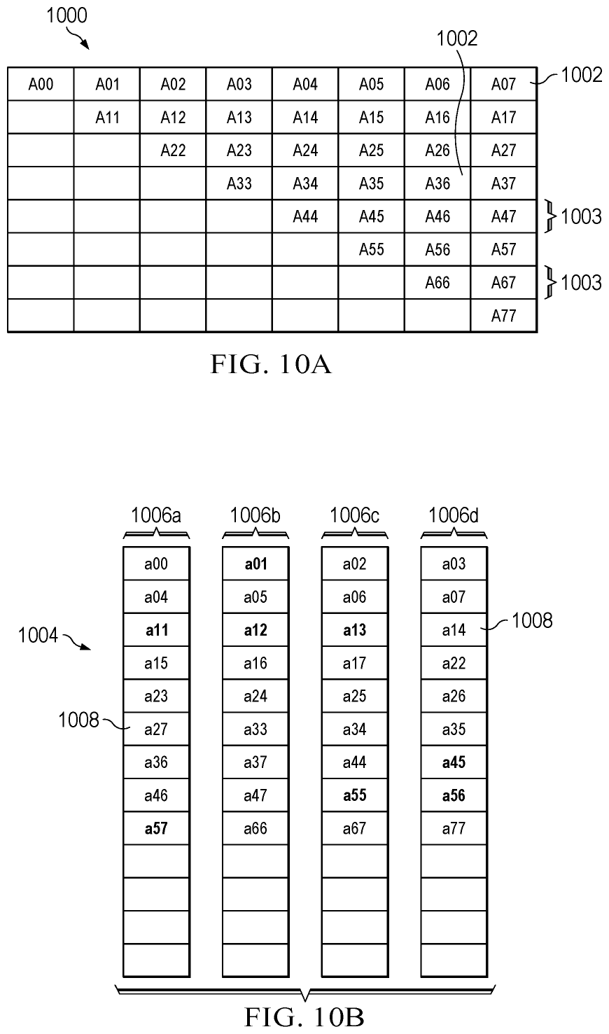

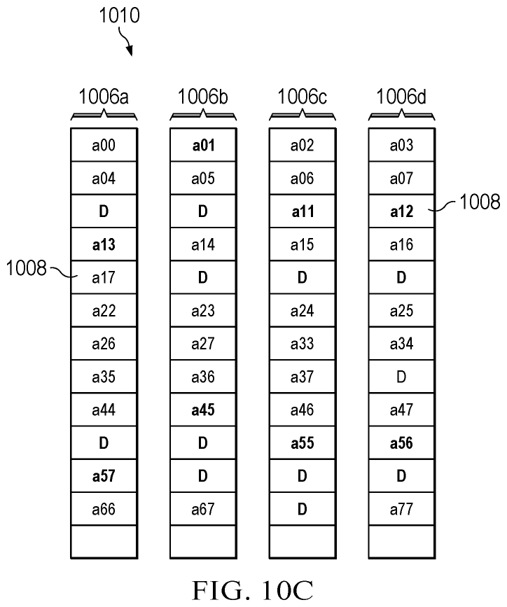

FIG. 2 is a functional block diagram of an example estimation subsystem 200. The estimation subsystem 200 corresponds to the capture subsystem 114 and the DPD estimator 116 of FIG. 1, and includes a capture subsystem 114, a model definition block 202, a matrix memory 204, a memory controller 205, a CG determination block 206, and a processor 208. The model definition block 202 includes a formation of model equations block 210 configured to form the model equations using the samples provided by the capture system 114, and a least squares aggregation block 212 that determines H^{H}×H and H^{H}×Z. The matrix memory 204 stores matrix A (the Hermitian matrix) and vector b. The memory controller 205 controls the matrix memory 204 to store matrix A and vector b received from the model definition block 202, and to read out matrix A or vector b in response to instructions from the CG determination block 206. Operation of the memory controller 205 is further discussed with respect to FIGS. 10A, 10B, and 10C. The CG determination block 206 includes a CG accelerator 214 and a coefficient vector memory 216. The processor 208 controls the CG accelerator 214 to use the matrices stored in the matrix memory 204 to iteratively update and determine coefficients in the coefficient vector x. In some examples, the processor 208 performs this control in response to instructions stored in updateable firmware in the processor 208. N can be configurable, such as from 4 to 512.

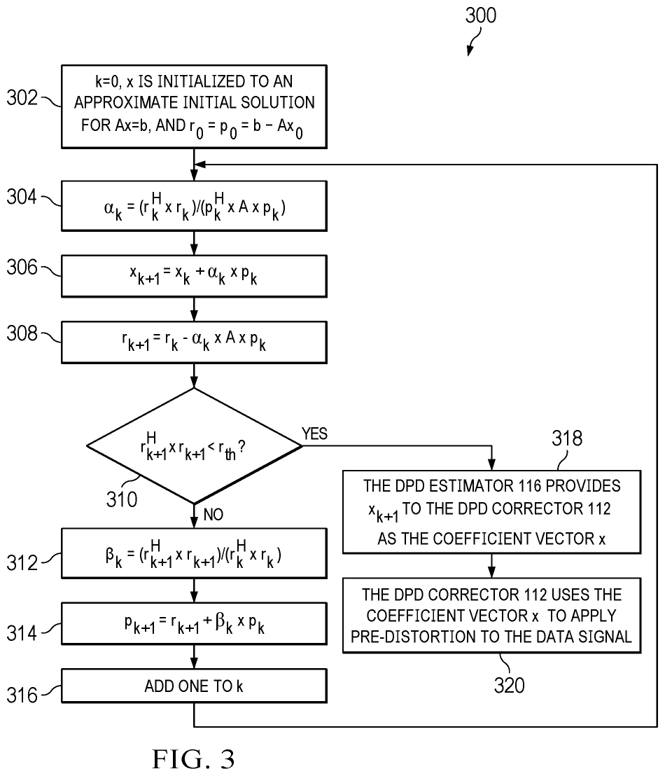

FIG. 3 shows a process diagram of an example conjugate gradient method 300. In step 302, an iterator k is initialized to zero, x₀ is initialized to an approximate initial solution vector for the coefficient vector x, and a residual vector rₖ and a working vector pₖ are initialized so that r₀=p₀=b−Ax₀. In some examples, the initial solution vector can be initialized to the solution in the previous iteration (steps 302 through 318) of the conjugate gradient method 300, or a zero vector (a vector full of zeroes), or a weighted average (or other synthesis) of previous solutions, or from a lookup table based on operating conditions such as temperature. In step 304, a scalar at is determined as shown in Equation 2:

αₖ(rₖ^{H}×rₖ)/(pₖ^{H}×A×pₖ) Equation 2

Note that rₖ^{H} is the conjugate transpose of the vector rₖ. Vectors rₖ^{H} and rₖ have dimensions 1×N and N×1, respectively (and similarly for pₖ^{H} and pₖ), so that the products determined in step 306 are each single values (1×1 matrices). In step 306, xₖ₊₁ is determined as shown in Equation 3:

xₖ₊₁=xₖ+αₖ×pₖ Equation 3

In step 308, rₖ₊₁ is determined as shown in Equation 4:

rₖ₊₁=rₖ−αₖ×A×pₖ Equation 4

In step 310, if rₖ₊₁^{H}×rₖ₊₁ is less than a threshold value rₜₕ, then process control jumps to step 318, otherwise the conjugate gradient method 300 continues with step 312.

In step 312, a scalar βₖ is determined as shown in Equation 5:

βₖ=(rₖ₊₁^{H}×rₖ₊₁)/(rₖ^{H}×rₖ) Equation 5

In step 314, pₖ₊₁ is determined as shown in Equation 6:

pₖ₊₁=rₖ₊₁+βₖ×pₖ Equation 6

In step 316, k is iterated by one, and the conjugate gradient method 300 repeats from step 304.

In step 318, the DPD estimator 116 provides xₖ₊₁ to the DPD corrector 112 as the coefficient vector x (the solution for Ax=b). In step 320, the DPD corrector 112 uses the coefficient vector x to apply pre-distortion to the DATA signal.

In some examples, determining the product A×pₖ, which is used within the loop (steps 304 to 316) in Equations 2 and 4, takes a significant portion of the total time taken to complete a CG iteration, from step 302 to step 318. In some examples, such as examples with 500 coefficients to determine, determining the product A×pₖ takes over 98% of the time used to complete the CG iteration. Memory configuration facilitating efficient parallelization of the A×pₖ determination, as controlled by the memory controller 205, is further discussed with respect to FIGS. 10A, 10B, and 10C. Memory configuration as addressed with respect to FIGS. 10A, 10B, and 10C also enables efficient parallelization of multiplication of an N×N Hermitian matrix (or other matrix similarly facilitating storage of only an upper or lower half without data loss) by an N×1 vector where N is relatively large.

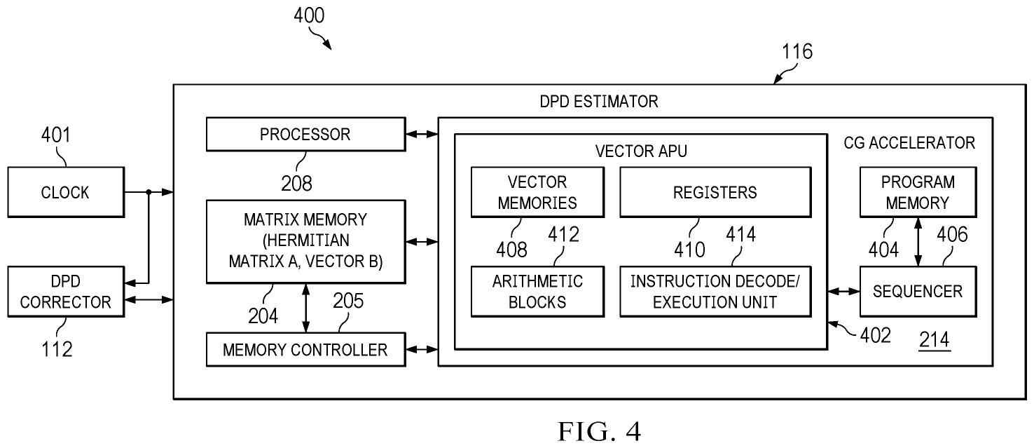

FIG. 4 shows a functional block diagram 400 of an example DPD estimator 116 and DPD corrector 112. The functional block diagram 400 includes the DPD corrector 112, the DPD estimator 116, and a clock 401 (for example, a system clock) that provides a clock signal to the DPD corrector 112 and the DPD estimator 116. The DPD estimator 116 includes the matrix memory 204, the memory controller 205, the processor 208, and the CG Accelerator 214. The CG Accelerator 214 includes a vector arithmetic processing unit (APU) 402, a program memory 404, and a sequencer 406. The vector APU 402 includes multiple vector memories 408, multiple registers 410, multiple arithmetic blocks 412, and an instruction decode/execution unit 414.

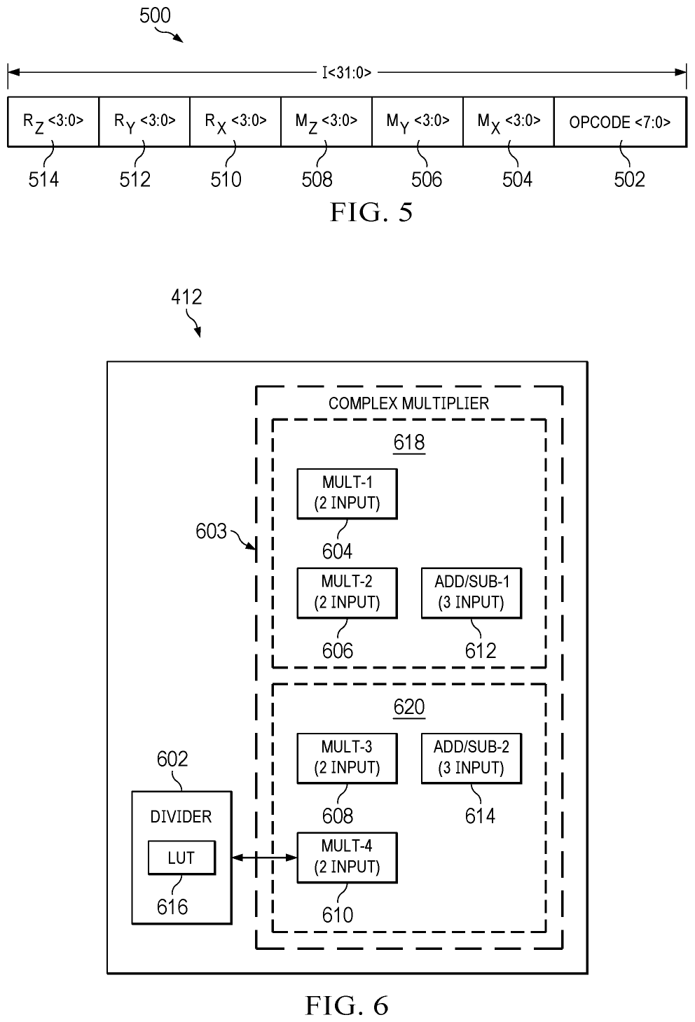

The processor 208 programs the program memory 404 with an ordered set of instructions for execution by the vector APU 402. For example, the program memory 404 can be sized as 64 lines, each capable of storing a 32 bit instruction. An example instruction format and an example instruction set, both for use in the CG accelerator 214, are described with respect to FIG. 5. The sequencer 406 reads the program memory 404 to provide the programmed instructions to the vector APU 402, for example in order. The instruction decode/execution unit 414 decodes the instructions, and controls the vector memories 408, registers 410, and arithmetic blocks 412 to perform accordingly. In some examples, the instruction decode/execution unit 414 is made up of a single interrupt service routine (ISR), executed from a corresponding flash memory. In some examples, the vector memories 408, registers 410, and arithmetic block 412 are configured to use double precision numbers. In some examples, double precision numbers include one sign bit, eleven exponent bits, and 52 fraction bits, totaling 64 bits.

The vector memories 408 are configured to hold/store vectors used during instruction execution, such as the (input and feedback) b matrix, and intermediate and final result forms of the (output coefficients) x vector. In some examples, the vector memories 408 include fourteen memories, each with 512 lines, with each line capable of storing 64 bits, so that each line can store one double precision number. The registers 410 are configured to store scalars, such as αₖ and βₖ as described with respect to Equations 2 and 5. In some examples, there are sixteen registers, each capable of storing 64 bits. The arithmetic blocks 412 include a divider, multiple multipliers, and multiple adders, and are further described with respect to FIGS. 6 through 9C.

FIG. 5 shows a bitwise format of an example instruction 500 for the CG accelerator 214 of FIG. 4. The instruction format 500 is 32 bits wide, and includes an eight bit operation code (OPCODE) 502 indicating the instruction type, a four bit M_{X} pointer 504 to a first input vector memory 408, a four bit M pointer 506 to a second input vector memory 408, a four bit M_{Z} pointer 508 to an output vector memory 408, a four bit Rx pointer 510 to a first input register 410, a four bit RY pointer 512 to a second input register 410, and a four bit R_{Z} pointer 514 to an output register 410. For example, within the instruction 500, the OPCODE 502 is in bits 0 through 7, the M_{X} pointer 504 is in bits 8 through 11, the M_{Y} pointer 506 is in bits 12 through 15, the M_{Z} pointer 508 is in bits 16 through 19, the Rx pointer 510 is in bits 20 through 23, the RY pointer 512 is in bits 24 through 27, and the R_{Z} pointer 514 is in bits 28 through 31. Accordingly, instructions listed below operate directly on hardware memory. Some OPCODES 502, such as OPCODES 502 indicating an operation using an external memory or corresponding to a process control change (such as a GOTO), indicate that some or all of bits 8 through 31 of the instruction 500 have meanings other than described above. An example list of OPCODE 502 names, with corresponding descriptions, is provided below in Table 1:

TABLE 1

| OPCODE name | Description |
|---|---|
| ECDOTPROD | M_{Z} + jM_{Z+1} = A × (M_{X} + jM_{X+1}) |
| | ECDOTPROD stands for complex dot product using an external |
| | memory. External memory refers to the matrix memory 204, which is |
| | external with respect to the CG accelerator 214. Execution of this |
| | instruction multiplies a matrix by a vector. Accordingly, execution of |
| | this instruction sequentially reads the vectors (for example, rows) of the |
| | Hermitian A matrix from the matrix memory 204, sequentially performs |
| | the dot product of each of the read vectors with a complex vector, and |
| | forms a dot product vector. Each element of the dot product vector is a |
| | dot product result. The complex vector has a real part stored in the |
| | vector memory 408 indicated by the M_{X} pointer 504. The complex |
| | vector has an imaginary part stored in a vector memory 408 that has an |
| | address one greater than the address indicated by the M_{X} pointer 504 |
| | (M_{X+1}). The real part of the dot product vector is accumulated and stored |
| | in the vector memory 408 indicated by the M_{Z} pointer 508. The |
| | imaginary part of the dot product vector is stored in a vector memory |
| | 408 that has an address one greater than the address indicated by the M_{Z} |
| | pointer 508 (M_{Z+1}). |
| ECVECSCALESUM | M_{Z} + jM_{Z+1} = b + R_{X} × (M_{X} + jM_{X+1}) |
| | ECVECSCALESUM refers to a complex vector multiplied by a scalar, |
| | then summed with an externally stored vector. Execution of this |
| | instruction reads a complex vector with real and imaginary parts stored |
| | as indicated by the M_{X} pointer 504 and M_{X+1}, and multiplies the |
| | complex vector by a scalar stored in the register 410 indicated by the R_{X} |
| | pointer 510. The b vector is read from the matrix memory 204, added |
| | to the product, and stored in the vector memories indicated by the M_{Z} |
| | pointer 508 and M_{Z+1}. (In some examples, a version of this instruction |
| | can use a complex scalar R_{X} + jR_{X+1}.) |
| CDOTPROD | R_{Z} + jR_{Z+1} = (M_{X} + jM_{X+1})^{H} · (M_{Y} + jM_{Y+1}) |
| | CDOTPROD stands for complex dot product. Execution of this |
| | instruction multiplies the conjugate transpose of a complex vector with |
| | real and imaginary parts stored in vector memories 408 respectively |
| | indicated by the M_{X} pointer 504 and M_{X+1}, by a complex vector with |
| | real and imaginary parts stored in the vector memories 408 respectively |
| | indicated by the M_{Y} pointer 506 and M_{Y+1}. The real and complex |
| | components of the product are stored in the registers 410 respectively |
| | indicated by the R_{Z} pointer 514 and R_{Z+1}. |
| CRDOTPROD | R_{Z} = (M_{X} + jM_{X+1})^{H} · (M_{X} + jM_{X+1}) |
| | CRDOTPROD refers to a self-dot product. Execution of this instruction |
| | is the same as for CDOTPROD, except that a single vector is specified, |
| | and the complex component of the product is not determined or stored. |
| | Note that because the dot product is between a vector and its own |
| | conjugate transpose, the imaginary part of the result will cancel out. |
| CVECSCALESUM | M_{Z} + jM_{Z+1} = M_{Y} + jM_{Y+1} + R_{X} × (M_{X} + jM_{X+1}) |
| | CVECSCALESUM refers to the sum of a complex vector with a |
| | complex vector multiplied by a scalar. This is used, for example, to |
| | determine xₖ + αₖ × pₖ. |
| RADD | R_{Z} = R_{X} + R_{Y} |
| | RADD stands for register addition. |
| RSUB | R_{Z} = R_{X} − R_{Y} |
| | RSUB stands for register subtraction. |
| RMULT | R_{Z} = R_{X} × R_{Y} |
| | RMULT stands for register multiplication. |
| RDIV | R_{Z} = R_{X}/R_{Y} |
| | RDIV stands for register division. |
| CMOV | M_{Z} + jM_{Z+1} ← M_{X} + jM_{X+1} |
| | CMOV stands for move a complex vector. Execution of this instruction |
| | causes a complex vector stored in vector memories 408 indicated by the |
| | Mx pointer 504 and M_{X+1} to be stored in vector memories 408 indicated |
| | by the M_{Z} pointer 504 and M_{Z+1}. |
| COMP | If R_{X} < R_{Y}, then set comp_status = 1. |
| | COMP refers to register comparison. On execution of this instruction, |
| | if a value stored in the register 410 indicated by the R_{X} pointer 510 and |
| | is less than a value stored in the register 410 indicated by the R_{Y} pointer |
| | 512, then a comparison status flag (comp_status) is set to a value |
| | indicating logical true, such as one. For example, the comp_status flag |
| | can be used to enable exiting a loop based on the value of the flag. |
| GOTO-LOOP | GOTO-LOOP refers to a loop-conditioned GOTO. Movement of the |
| | program counter (PC) to a location indicates a jump. If the jump is to a |
| | location earlier in the instruction list, then the jump causes a loop. |
| | Movement of the PC to a location after the GOTO-LOOP instruction |
| | corresponds to exiting the loop. On execution of the GOTO-LOOP |
| | instruction, if the loop has been iterated less than a number of times |
| | specified in bits 16 through 31 of the instruction 500, then the PC is |
| | moved to a location specified in bits 8 through 15 of the instruction 500. |
| | If the loop has been iterated more than the specified number of times, or |
| | comp_status is set to logical true, then the PC exits the loop. |
| COND | COND refers to a status-conditioned GOTO. On execution of this |
| | instruction, if comp_status is set to logical true, then process control is |
| | transferred to an instruction in the program memory 404 at address A. |
| | Otherwise, process control is transferred to an instruction in the program |
| | memory 404 at address B. Address A can be specified at, for example, |
| | bits 8 through 15 of the instruction 500; address B can be specified at, |
| | for example, bits 16 through 23 of the instruction 500. |
| PAUSE | PAUSE causes program execution to temporarily halt. On execution of |
| | this instruction, execution is paused and the processor 208 is interrupted |
| | to indicate the program has completed or otherwise exited. |

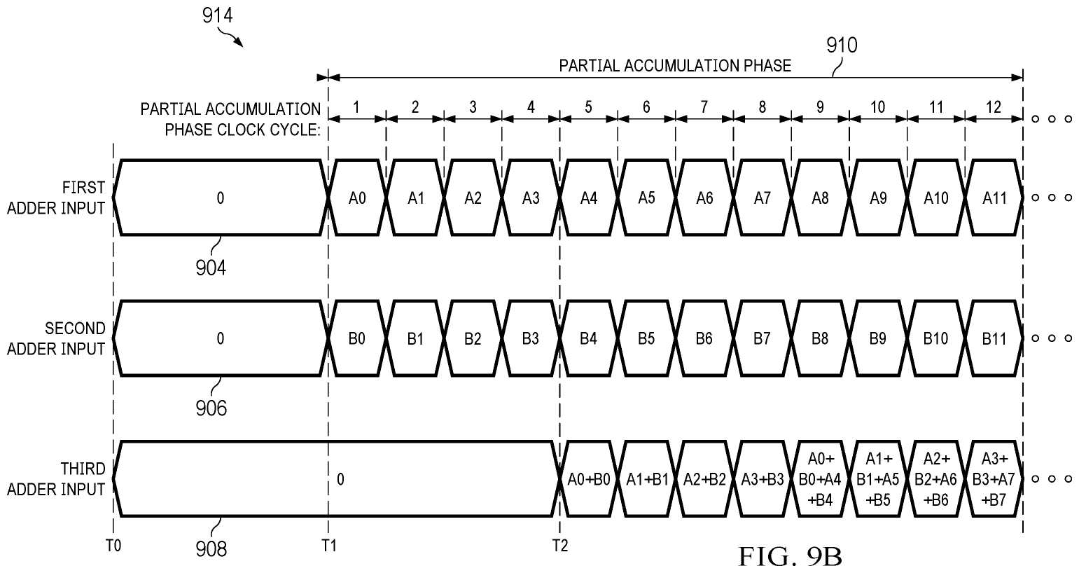

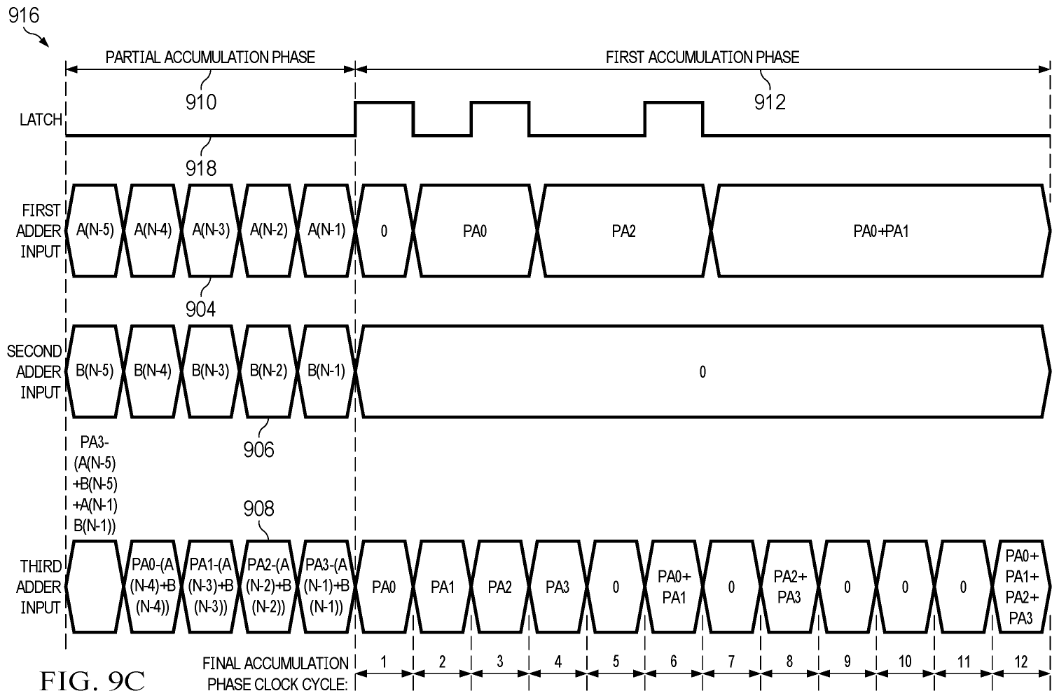

The instruction set can also include real variants (real-type instructions) of the instructions described above for manipulating complex vectors or external matrices (complex-type instructions). Such real-type instructions accept real vectors or matrices as inputs and which output real vectors. In some examples, a reduced set of arithmetic blocks 412 can be used to execute instructions for manipulating real vectors. Execution of real-type instructions is further described below with respect to FIG. 9C.

FIG. 6 shows a functional block diagram of an example of the arithmetic blocks 412 of FIG. 4. The arithmetic blocks 412 include a divider 602 and a complex multiplier 603. The complex multiplier 603 includes a first two-input multiplier (MULT-1) 604, a second two-input multiplier (MULT-2) 606, a third two-input multiplier (MULT-3) 608, a fourth two-input multiplier (MULT-4) 610, a first three-input adder (ADD/SUB-1) 612, and a second three-input adder (ADD/SUB-2) 614. In some examples, each of the arithmetic blocks 412 performs arithmetic using double precision numbers.

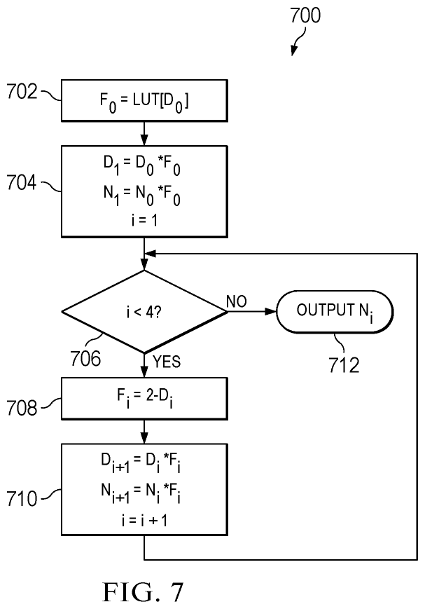

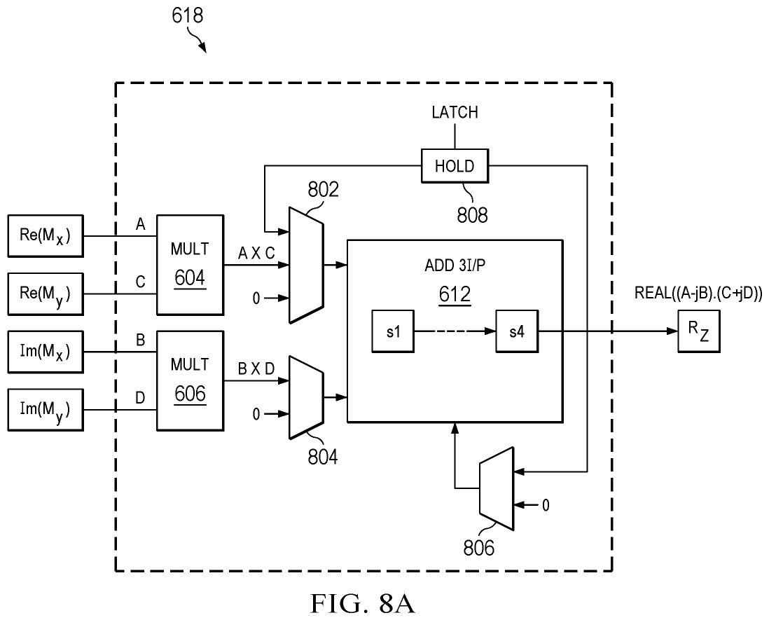

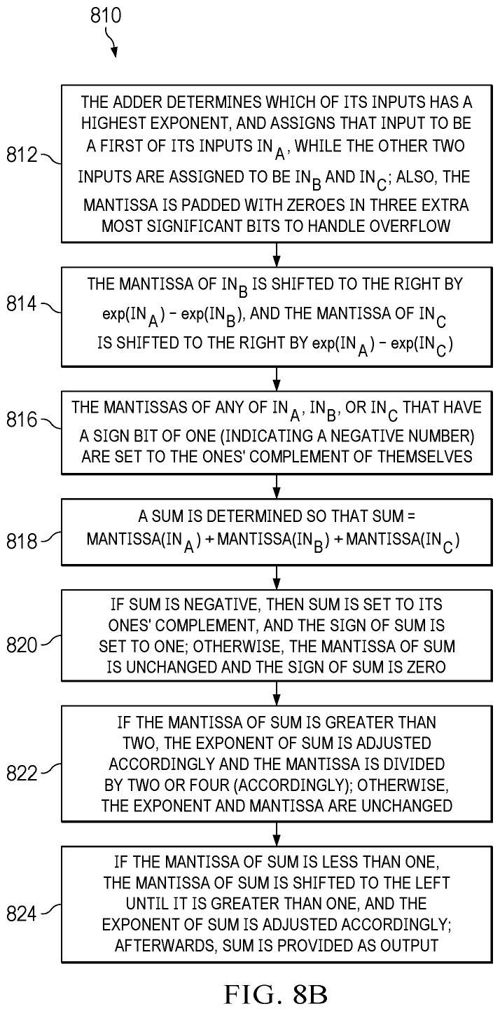

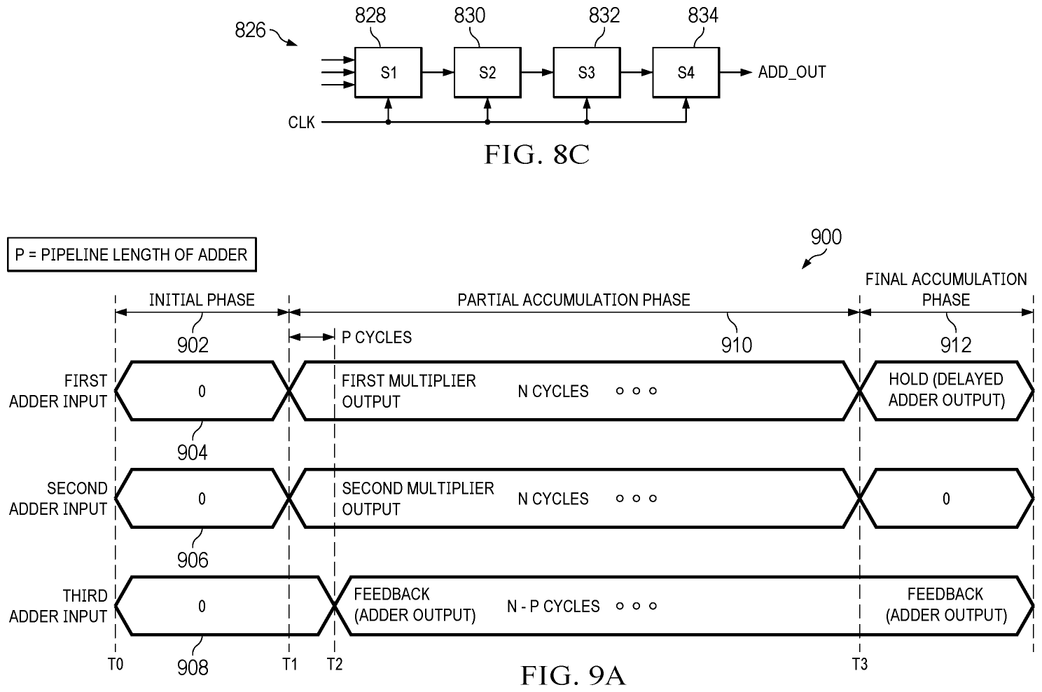

In some examples, multiplier-1 604, multiplier-2 606, multiplier-3 608, and multiplier-4 610 each have a throughput of one multiplication per cycle of the clock 401, with a pipeline that takes three clock cycles, from input to output, to process a multiplication. In some examples, adder-1 612 and adder-2 614 each have a throughput of one addition per clock cycle, with a pipeline that takes four clock cycles, from input to output, to process an addition. In some examples, the divider 602 is configured to use one or more of multiplier-1 604, multiplier-2 606, multiplier-3 608, or multiplier-4 610 to perform division. This enables a reduction in die area overhead. In some examples, the divider 602 uses the Goldschmidt algorithm to perform division, and includes a lookup table (LUT) 616. The LUT 616 has seven bits input width and eight bits output width. Further description of the divider 602 and LUT 616 is provided with respect to FIG. 7. Further description of the multiplier-1 604, multiplier-2 606, multiplier-3 608, and multiplier-4 610, and adder-1 612 and adder-2 614, is provided with respect to FIGS. 8A through 9C.

In some examples, two of the multipliers 604, 606, 608, or 610 and one of the adders 612 or 614 are used together to determine a real part or an imaginary part of a complex vector arithmetic operation, such as a complex vector dot product. For example, multiplier-1 604, multiplier-2 606, and adder-1 612 can together be viewed as a real part block 618, outputting a real part of a complex vector arithmetic operation. Similarly, multiplier-3 608, multiplier-4 610, and adder-2 614 can together be viewed as an imaginary part block 620, outputting an imaginary part of a complex vector arithmetic operation. In some examples, different combinations of the multiplier-1 604, multiplier-2 606, multiplier-3 608, and multiplier-4 610, and adder-1 612 and adder-2 614, can be used to determine a real part or an imaginary part of the output of a complex vector arithmetic operation.

FIG. 7 shows a diagram of an example division process 700 of the divider 602 of FIG. 6. The division process 700 uses an example of the Goldschmidt algorithm. The division process 700 is iterative, multiplying the dividend and the divisor (denominator) by a common factor Fᵢ. The dividend can be viewed as a numerator N₀, and the divisor can be viewed as a denominator D₀. The iterated denominator Dᵢ can be expressed as one plus some delta, and the common factor Fᵢ can similarly be expressed as one minus the delta, so that Dᵢ=1+Δ and Fᵢ=1−Δ. The denominator is iteratively updated so that Dᵢ₊₁=Dᵢ×Fᵢ=1−Δ². Accordingly, if the denominator converges to one, then the numerator quadratically converges to the quotient.

In step 702, D₀ is provided as input to the LUT 616, and the LUT 616 provides an initial, approximate common factor F₀ in response, so that F₀=LUT[D₀]. In step 704, the divider 602 uses one of the multipliers 604, 606, 608, or 610 to multiply each of N₀ and D₀ by F₀, so that N₁=N₀×F₀ and Dᵢ=D₀×F₀, and initializes the iterator so that i=1. In step 706, if i<4, then the process 700 continues at step 708, otherwise the process continues at step 712. In step 708, the common factor is set as Fᵢ=2−Dᵢ. Note that 1−Δ=2−Dᵢ; the latter expression is used in execution because 2−Dᵢ is efficiently expressible in binary arithmetic. In step 710, the divider 602 uses a multiplier (multiplier-1 604, multiplier-2 606, multiplier-3 608, or multiplier-4 610) to multiply Nᵢ and Dᵢ by Fᵢ, so that Nᵢ₊₁=Nᵢ×Fᵢ and Dᵢ₊₁=Dᵢ×Fᵢ, adds one to the current value of i (i==i+1), and loops the process 700 back to step 706. In step 712, the divider 602 outputs Nᵢ.

In some examples, each iteration of the loop, steps 706 to 710, doubles the precision of the determined quotient Nᵢ. For example, if there is initially eight bit precision, then after the first iteration there is 16 bit precision, and after three iterations there is 64 bit precision, such as in a double precision number as described above. In some examples, the divider 602 begins performing the process 700 and begins providing inputs to a multiplier 604, 606, 608, or 610 in a first cycle of the clock 401. Counting from this first clock cycle, the multiplier 604, 606, 608, or 610 receives inputs from the divider 602 on the first, second, fourth, fifth, seventh, eighth, tenth, and eleventh clock cycles, and the divider 602 outputs Nᵢ on the fourteenth clock cycle. Accordingly, the division process 700 takes fourteen cycles.

FIG. 8A shows a functional block diagram of the real part block 618 as shown in FIG. 6. In addition to multiplier-1 604, multiplier-2 606, and adder-1 612, the real part block 618 also includes a first multiplexer 802, a second multiplexer 804, a third multiplexer 806, and a hold block 808. A first input of multiplier-1 604 receives a real part A of a first vector (Re(M_{X})), and a second input of multiplier-1 604 receives a real part C of a second vector (Re(M_{Y})). A first input of multiplier-2 606 receives an imaginary part B of the first vector (Im(M_{X})), and a second input of multiplier-2 606 receives an imaginary part D of the second vector (Im(M_{Y})). The imaginary part block 620 is essentially the same as the real part block 618, except that first and second inputs of multiplier-3 608 respectively receive the real part of the first vector and the imaginary part of the second vector, and the first and second inputs of multiplier-4 610 respectively receive the imaginary part of the first vector and the real part of the second vector.

Multiplier-1 604 outputs to a first input of the first multiplexer 802, a second input of the first multiplexer 802 receives a numerical zero input, and a third input of the first multiplexer 802 is connected to an output of the hold block 808. The first multiplexer 802 outputs to a first input of adder-1 612. Multiplier-2 606 outputs to a first input of the second multiplexer 804, and a second input of the second multiplexer 804 receives a numerical zero input. The second multiplexer 804 outputs to a second input of adder-1 612. A third input of adder-1 612 is connected to the output of the third multiplexer 806. Adder-1 612 provides an output of the real part block 618. The output of adder-1 612 is also connected to a data input of the hold block 808, and to a first input of the third multiplexer 806. The hold block 808 is configured to receive a latch signal at a control input of the hold block 808. A second input of the third multiplexer 806 receives a numerical zero.

In an example in which the vector APU 402 performs a complex dot product on vectors A+jB and C+jD as (A+jB)^{H} multiplied by C+jD, the output of the real part block 618 is the real part of (A−jB)−(C+jD). In an example in which the vector APU 402 performs a complex dot product on vectors A+jB and C+jD as (A+jB)^{T} multiplied by C+jD, the output of the real part block 618 is the real part of (A+jB)−(C+jD). Whether the former example or the latter example complex dot product method is used can depend on whether B or negative B is provided as an input to multiplier-2 606.

An example addition process used by adder-1 612 is provided with respect to FIG. 8B. Further description of the four stage pipeline of adder-1 612 is provided with respect to FIG. 8C. Further description of timing and of a partial accumulation process used by adder-1 612 is provided with respect to FIGS. 9A through 9C. Description of structure, function, and signal timing of adder-1 612 and the real part block 618 with respect to FIG. 8A through 9C is also applicable to the imaginary part block 620 and corresponding multiplier-3 608 and multiplier-4, adder-2 614, multiplexers, and hold block (multiplexers and hold block of the imaginary part block 620 are not pictured herein).

FIG. 8B shows a diagram of an example addition process 810 of adder-1 612 of FIG. 6. In step 812, the adder determines which of its inputs has a highest exponent, and assigns that input to be a first of its inputs IN_{A}, while the other two inputs are assigned to be IN_{B} and IN_{C}; also, the mantissa is padded with zeroes in three extra most significant bits to handle overflow. A mantissa is the fraction portion (as distinct from the exponent and sign portions) in the representation of a numerical value. In step 814, the mantissa of IN_{B} is shifted to the right by exp(IN_{A})−exp(IN_{B}), and the mantissa of IN_{C} is shifted to the right by exp(IN_{A})−exp(IN_{C}), where exp(X) refers to the exponent portion in the representation of a numerical value X; in a binary representation, the exponent is doubled by shifting one to the left, and halved by shifting one to the right. In step 816, the mantissas of any of IN_{A}, IN_{B}, or IN_{C} that have a sign bit of one (indicating a negative number) are set to their respective ones' complement, so that zeroes become ones and ones become zeroes. Adding a number A to the ones' complement of a number B subtracts B from A (for binary A and B; in some examples, ones' complement subtraction results in a one LSB error; in some examples, a one LSB error is negligible).

In step 818, a sum is determined so that SUM=mantissa(IN_{A})+mantissa(IN_{B})+mantissa(IN_{C}). In step 820, if SUM is negative, then SUM is set to its ones' complement, and the sign of SUM is set to one; otherwise, the mantissa of SUM is unchanged and the sign of SUM is zero (positive). The mantissa of a double precision number should be between one and two. Accordingly, in step 822, if the mantissa of SUM is greater than two (there is an overflow), the exponent of SUM is adjusted accordingly and the mantissa of SUM is divided by two or four to make the mantissa of SUM less than two); otherwise, the exponent and mantissa are unchanged. In step 824, if the mantissa of SUM is less than one, then the mantissa of SUM is shifted to the left until the mantissa of SUM is greater than one, the exponent of SUM is adjusted accordingly; afterwards, SUM is provided as output.

FIG. 8C shows a functional block diagram of an example pipeline 826 of adder-1 612 of FIG. 6. The pipeline 826 includes a first stage 828, a second stage 830, a third stage 832, and a fourth stage 834. The first stage 828 includes a first input, a second input, and a third input. The inputs of the first stage 828 are the inputs of adder-1 612. The fourth stage 834 includes an output. The output of the fourth stage 834 is the output (ADD_OUT) of adder-1 612. Outputs of the first stage 828, the second stage 830, and the third stage 832 are respectively connected to data inputs of the second stage 830, the third stage 832, and the fourth stage 834. In some examples, different ones of the stages 828, 830, 832, and 834 have different numbers of inputs or outputs. In some examples, different ones of the stages 828, 830, 832, and 834 have different bit widths, and respective inputs or outputs are different numbers of bits wide. The first stage 828, the second stage 830, the third stage 832, and the fourth stage 834 are respectively clocked by a clock signal (CLK) received from the clock 601 at respective clock inputs of the first, second, third, and fourth stages 828, 830, 832, and 834, so that each of the stages 828, 830, 832, and 834 takes one clock cycle to process its respective input(s). Different ones of the stages 828, 830, 832, and 834 of adder-1 612 perform different mathematical operations on respective inputs. The output of adder-1 612 uses double precision representation.

FIG. 9A shows a timing diagram illustrating example signal timing 900 of the real part block 618. In an initial phase, starting at time T0, multiplier-1 604 and multiplier-2 606 receive inputs, but the corresponding multiplication pipelines have not yet finished processing the inputs. Accordingly, during the initial phase 902, the first input 904 (first adder input 904) of adder-1 612 receives a zero from the first multiplexer 802 and the second input 906 (second adder input 906) of adder-1 612 receives a zero from the second multiplexer 804, because multiplier-1 604 and multiplier-2 606 have not yet produced valid outputs. Also, the third input 908 (third adder input 908) of adder-1 612 receives a zero from the third multiplexer 806, because adder-1 612 has not yet produced a valid output.

At T1, multiplier-1 604 and multiplier-2 606 finish processing their initial inputs and provide a corresponding output, marking the beginning of the partial accumulation phase 910. Partial accumulation refers to different running sums accumulated within each pipeline stage of adder-1 612. These running sums—referred to herein as partial accumulations—are maintained using the feedback provided by the third input 908 of adder-1 612. When the different partial accumulations are added together, they equal the sum of the addends received by the first and second inputs 904 and 906 of adder-1 612.

In the example described with respect to FIG. 6, multiplier-1 604 and multiplier-2 606 each include a pipeline that takes three clock cycles from receipt of input to providing output. Accordingly, in this example, the partial accumulation phase 910 begins three clock cycles after multiplier-1 604 and multiplier-2 606 receive inputs. During the partial accumulation phase 910, multiplier-1 604 and multiplier-2 606 continue to provide new outputs on each clock cycle until they finish processing the available inputs, at which point the partial accumulation phase 910 ends. At time T2, P_{A} cycles after the partial accumulation phase 910 starts, adder-1 612 begins to provide itself feedback (the output of adder-1 612) at the third input 908 of adder-1 612. Here, P_{A} is the number of stages in the pipeline of adder-1 612.

At time T3, multiplier-1 604 and multiplier-2 606 have finished processing the available inputs, at which point the partial accumulation phase 910 ends and the final accumulation phase 912 begins. During the final accumulation phase 912, the LATCH signal provided to the control input of the hold block 808 is successively asserted and de-asserted so that the hold block 808 sequentially stores different outputs of adder-1 612. The hold block 808 provides these partial sums to the first input 904 of adder-1 612. This enables the accumulated partial sums to be added together to produce an aggregate, final sum as output of adder-1 612. The second input 906 of adder-1 612 receives a zero from the second multiplexer 804. The third input 908 of adder-1 612 is feedback from the output of adder-1 612. Accordingly, the third input 908 of adder-1 612 receives different partial sums from those provided by the hold block 808 to the first input 904 of adder-1 612.

FIG. 9B shows a timing diagram illustrating example signal timing 914 of the real part block 618, including additional detail relating to partial accumulation. The signal timing 914 corresponds to the signal timing 900 of FIG. 9A, and provides additional detail differentiating the different inputs received over time by adder-1 612. In particular, the signal timing 914 facilitates description below of partial accumulation: during the partial accumulation phase 910, each pipeline stage of adder-1 612, such as the first stage 828, the second stage 830, the third stage 832, and the fourth stage 834, separately accumulates a running sum of a different, corresponding, every-fourth-clock-cycle output of adder-1 612.

Accordingly, during a given clock cycle C in the partial accumulation phase 910, a first partial accumulation PA1 is incorporated into processing of the first stage 828, a second partial accumulation PA2 is incorporated into processing of the second stage 830, a third partial accumulation PA3 is incorporated into processing of the third stage 832, and a fourth partial accumulation PA4 is incorporated into processing of the fourth stage 834. In a next clock cycle C+1, PA4 is incorporated into processing of the first stage 828 (plus addends received on clock cycle C+1 by the first and second inputs 904 and 906 of adder-1 612), PA1 is incorporated into processing of the second stage 830, PA2 is incorporated into processing of the third stage 832, and PA3 is incorporated into processing of the fourth stage 834.

Partial accumulation is enabled by feedback of the output of adder-1 612 to the third input 908 of adder-1 612. On a first clock cycle of the partial accumulation phase 910, the first input 904 of adder-1 612 receives A0 (corresponding to A×C in FIG. 8A), the second input 906 receives B0 (corresponding to B×D in FIG. 8A), and the third input 908 receives zero from the third multiplexer 806. On a second clock cycle of the partial accumulation phase 910, the first input 904 receives A1, the second input 906 receives B1, and the third input 908 receives zero from the third multiplexer 806. The third input 908 continues to receive numerical zero until the fifth clock cycle of the partial accumulation phase 910, when adder-1 612 outputs A0+B0, so that the first input 904 receives A4, the second input 906 receives B4, and the third input 908 receives A0+B0. Similarly, on the sixth clock cycle of the partial accumulation phase 910, the first input 904 receives A5, the second input 906 receives B5, and the third input 908 receives A1+B1. On the ninth clock cycle, adder-1 612 outputs A0+B0+A4+B4, and on the tenth clock cycle, adder-1 612 outputs A1+B1+A5+B5. Accordingly, during the partial accumulation phase 910, the output of adder-1 612 on an n^{th} clock cycle of the partial accumulation phase 910 can be represented as shown in Equation 7:

$$Output = {\sum }_{k = 0}^{k = \frac{n - 1 - ( n - 1 ) mod 4}{4} 1} ( A ( 4 k + m ) + B ( 4 k + m ) ) \qquad Equation 7$$

In Equation 7, m is an offset so that m=(n−1)mod 4; mod is the modulus operation; A(0) is A0, A(1) is A1, and so on; and B(0) is B0, B(1) is B1, and so on. The offset m corresponds to a partial accumulation determined by a starting clock cycle of the partial accumulation. For example, n=13 means that m=0, corresponding to a partial accumulation starting on a first clock cycle in which adder-1 612 received valid output from multiplier-1 604 and multiplier-2 606. For n=13, the output of adder-1 612 is A0+B0+A4+B4+A8+B8. In another example, n=15 means that m=2, corresponding to a partial accumulation starting on a third clock cycle, and the output of adder-1 612 is A2+B2+A6+B6+A10+B10.

The pipeline of adder-1 612 has four stages, each stage taking one clock cycle to complete. Examples in which an adder has a P_{A} stage pipeline, each pipeline stage taking one clock cycle to complete, are described by Equation 8:

$$Output = {\sum }_{k = 0}^{k = \frac{n - 1 - ( n - 1 ) mod 4}{4} 1} ( A ( Pk + m ) + B ( Pk + m ) ) \qquad Equation 8$$

FIG. 9C shows a timing diagram illustrating example signal timing 916 of the real part block 618, including additional detail relating to a final accumulation phase. As described above, the partial accumulation phase 910 ends after the first clock cycle during which the pipelines of multiplier-1 604 and multiplier-2 606 are empty and, accordingly, the first and second inputs 904 and 906 of adder-1 612 consume their last non-feedback inputs corresponding to a single instruction (for example, as described with respect to FIG. 5 and Table 1). In the signal timing 904, the first and second inputs 904 and 906 are represented as shown in Equation 7, such as A(N−5), indicating the fifth-to-last value received at the first input 904 of adder-1 612; and B(N−1), indicating the last value received as the first input 904 of adder-1 612. N is the total number of values (distinct outputs of multiplier-1 604 or multiplier-2 606) received by the first and second inputs 904 and 906 of adder-1 612. In the signal timing 916 of FIG. 9C, PA0 is the first partial accumulation (m=0) after the end of the partial accumulation phase 910, PA1 is the second partial accumulation (m=1) after the end of the partial accumulation phase 910, and so on. In the illustrated example, N happens to be divisible by four—PA3 is the last partial accumulation output by adder-1 612 during the partial accumulation phase 910. In some examples, N is not divisible by four.

During the final accumulation phase 912, the partial accumulations are added together to produce a final output of the real part block 618 in response to a corresponding instruction. In a first clock cycle of the final accumulation phase 912, the control input of the hold block 808 receives an asserted LATCH signal 918, such as a logical one, causing the hold block 808 to latch its input—the output of adder-1 612 during the first clock cycle, which is PA0—in response to the CLK signal of the clock 401; however, during a clock cycle, the hold block 808 latches so that its output does not change until the end of the clock cycle. The first input 904 receives a numerical zero from the first multiplexer 802 because the hold block 808 has not yet latched and provided a valid output. The second input 906 receives a numerical zero from the second multiplexer 804 throughout the final accumulation phase 912, because there is no valid output from multiplier-2 606. The third input 908 receives the output of adder-1 612 during the first clock cycle, which is PA0.

In a second clock cycle of the final accumulation phase 912, the LATCH signal 918 is de-asserted, such as to a logical zero, so that the hold block 808 will continue to hold its output (PA0) constant, and will not latch its input (PA1) in response to the CLK signal. Accordingly, the hold block 808 outputs, and the first input 904 receives, PA0. The third input 908 receives the output of adder-1 612 during the second clock cycle, which is PA1.

In a third clock cycle of the final accumulation phase 912, the LATCH signal 918 is asserted, causing the hold block 808 to latch the output of adder-1 612 during the third clock cycle, which is PA2; but the hold block 808 continues to output, and the first input 904 continues to receive, PA0 until the end of the third clock cycle. The third input 908 receives the output of adder-1 612 during the third clock cycle, which is PA2.

In a fourth clock cycle of the final accumulation phase 912, the LATCH signal 918 is de-asserted. Accordingly, the hold block 808 outputs, and the first input 904 receives, PA2. The third input 908 receives the output of adder-1 612 during the fourth clock cycle, which is PA3. In a fifth cycle of the final accumulation phase, adder-1 612 outputs PA0. PA0 was already added to PA1 in the second clock cycle, and PA2 was added to PA3 in the fourth clock cycle. The only remaining new addition to perform is to add PA0+PA1 to PA2+PA3 to produce the final output. These inputs become available in the sixth and eighth clock cycles. Accordingly, the inputs to adder-1 612 in the fifth clock cycle don't matter.

In a sixth clock cycle of the final accumulation phase 912, the LATCH signal 918 is asserted, causing the hold block 808 to latch the output of adder-1 612 during the third clock cycle, which is PA0+PA1. The first input 904 receives PA2, and the third input 908 receives PA0+PA1. The third input 908 actually does not matter during the sixth clock cycle; for example, it could receive zero without interrupting function. PA0+PA1 is shown as the third input 908 to clearly indicate within FIG. 9C what the hold block 808 is latching during the sixth clock cycle. In a seventh clock cycle of the final accumulation phase 912, the LATCH signal 918 is de-asserted. The hold block 808 outputs, and the first input 904 receives, PA0+PA1. The third input 908 does not matter during the seventh clock cycle.

In an eighth clock cycle of the final accumulation phase 912, the first input 904 receives PA0+PA1 from the hold block 808, and the third input 908 receives PA2+PA3 from the output of adder-1 612. During ninth, tenth, and eleventh cycles of the final accumulation phase 912, pipeline stages of adder-1 612 process the addition started on the eighth clock cycle. On the twelfth clock cycle of the final accumulation phase 912, adder-1 612 provides as output PA0+PA1+PA2+PA3. Accordingly, for two complex vectors each containing N elements, processed by a real part block 618 with two two-input multipliers 604 and 606 each with P_{M} pipeline stages that each take one cycle to perform and a three-input adder 612 with P_{A} pipeline stages that each take one cycle to perform, the real part of a complex dot product can be determined in P_{M}+N+P_{A}×(ceiling(1+log₂ P_{A})) clock cycles, not including clock cycles required for memory read and write accesses, and interaction delays between different functional blocks of the DPD estimator 116. (The ceiling operation rounds up to the next integer.) Instruction decoding is an example of an interaction delay. In some examples in which P_{M} equals three, P_{A} equals four, and including memory accesses and interaction delays, the total time taken to execute a complex dot product instruction (CDOTPROD) equals N+22 clock cycles. Similarly, the total time taken to execute a complex multiplication of a Hermitian matrix with a vector instruction (ECDOTPROD), such as A×pₖ, is (N+23)×N, which is approximately N² for large N.

In some examples, performance of a real-type instruction can use a single multiplier (such as multiplier-1 604) and a single adder (such as adder-1 612) of a single block (such as real part block 618). In some such examples, a multiplexer (such as the second multiplexer 804) corresponding to an unused multiplier (such as multiplier-2 606) is set to output a zero throughout execution of the real variant instruction. In alternative examples, only a single multiplier and a single adder are present in a configuration used to perform a real-type instruction. In some examples, the partial accumulation phase 910 and final accumulation phase 912 for a real-type instruction are the same as for a complex-type instruction, except that values of the second adder input 906 are set to zero—or are not present—for the real-type instruction.

FIG. 10A shows an example of a Hermitian matrix 1000 as stored in the matrix memory 204 of FIGS. 2 and 4. As shown, the Hermitian matrix 1000 can be stored as an upper triangle of the full Hermitian matrix because of conjugate symmetry. (In some examples, the Hermitian matrix can be stored as the lower triangle, or in another manner retaining one of each complex conjugate pair.) An upper triangle of a matrix refers to elements 1002 of the matrix for which a column index is equal to or higher than a corresponding row index, and a lower triangle of the matrix refers to elements 1002 of matrix for which the column index is equal to or lower than the corresponding row index. For example, element 1002 a24 (row two, column four) is the complex conjugate of a42, and element 1002 a13 is the complex conjugate of a31. The elements a42 and a31 are not shown because, as conjugates to values that are stored, they do not need to be stored. Accordingly, if an operation requires a42, then element 1002 a24 can be read, and the sign of the imaginary part of element 1002 a24 can be inverted. In other words, if element 1002 a24 equals a+jb, then a42 equals a−jb, where b can be positive or negative.

FIG. 10B illustrates an example data layout 1004 of the matrix memory 204 of FIGS. 2 and 4. M-way parallelization of performance of matrix math operations by the CG Accelerator 214—operations that access the matrix memory 204, such as ECDOTPROD—uses M math units, where each math unit is a complex multiplier that includes four multipliers and two adders. For example, four-way parallelization can use four real part blocks 618 and four imaginary part blocks 620. Accordingly, the Hermitian matrix 1000 is stored in four different memories 1006a, 1006b, 1006c, and 1006d that are separately, simultaneously readable. The Hermitian matrix 1000 is stored so that elements 1002 in a row 1003 of the Hermitian matrix 1000, starting with the first element in the row 1003, are sequentially stored in memory 1006a, then 1006b, then 1006c, then 1006d; and the first element of the next row 1003 starts with the next memory 1006a, 1006b, 1006c, or 1006d after the one occupied by the last element 1002 of the previous row 1003. Accordingly, a00 is stored in 1006a, a01 is stored in 1006b, and so on until a07 is stored in 1006d; and then a11, starting the next row 1003, is stored in 1006a, and so on.

In some examples, to execute an M-way parallelized operation using the CG accelerator 214, M elements 1002, corresponding to M consecutive rows 1003 in a single column of the Hermitian matrix 1000, are read per clock cycle from corresponding memories 1006a, 1006b, 1006c, or 1006d. In the densely stored data layout 1004, a corresponding read of matrix data can cause a collision between multiple entries 1008 in a single memory 1006 that need to be accessed at the same time, such as a01 and a12 (or a21, which is not stored, but can be obtained by reading a12 and taking its complex conjugate). Accordingly, multiple reads would need to be performed in order to access multiple elements 1002 that are stored in the same memory 1006 and required as inputs in the same clock cycle of an operation being executed by the CG accelerator 214. This would cause a delay of one or more clock cycles.

FIG. 10C illustrates an example data layout 1010 of the matrix memory 204 of FIGS. 2 and 4. To avoid collisions, rows 1003 of the (upper triangle) Hermitian matrix 1000 can be stored as described with respect to the data layout 1004 of FIG. 10B, but with dummy entries, marked “D” in the data layout 1010, padding the ends of rows 1003 as stored in the memories 1010. The number of dummies DUM for a row 1003 of length LEN is selected so that the number of entries 1008 used by the padded row 1003 equals either 4k or 4k+2 (consistently one or the other for all rows of the Hermitian matrix 1000), for some number k that can be different for different rows. Padding so that the number of entries 1008 used by the padded row 1003 equals 4k+2 is illustrated. LEN is the length in elements 1002 of a row 1003 as stored in the memories 1006a, 1006b, 1006c, and 1006d—accordingly, the first row 1003 (starting with a00) has eight elements 1002, the second row 1003 (starting with a11) has seven elements, and so on. This relationship is shown in Equation 9:

(LEN+DUM)mod 4=0 or 2 Equation 9

Accordingly, the first row 1003 is padded with two dummies (ten equals eight plus two), the second row 1003 is padded with three dummies (same), the third row is padded with no dummies (six equals four plus two), and so on. It can be seen that for the four memories 1006a, 1006b, 1006c, and 1006d, padding follows the pattern two dummies, then three, then zero, then one (2, 3, 0, 1). The number of dummies can start on any of two, three, zero, or one, then proceed in that pattern, with the starting point depending on the size of the Hermitian matrix 1000. For example, an upper triangle of a 9×9 Hermitian matrix would start with one dummy, then two, then three, then zero, and so on (1, 2, 3, 0). Padding the ends of rows of a lower triangle of an Hermitian matrix, as stored in four matrix memories, is performed so that the number of entries used by the padded row 1003 equals 4k+1 or 4k+3. This relationship is shown in Equation 10:

(LEN+DUM)mod 4=1 or 3 Equation 9

Padding the matrix memory 204 with dummies can also be used to avoid clashes for two-way parallelism; and non-parallel processing also remains supported. In some examples, a data layout 1004 padded to enable M-way parallel execution can also be used to enable m-way parallel execution, where m is an integer factor of M.

Referring back to FIGS. 4 and 5, the processor 208 can be used to change to instructions stored in the program memory 404. These changes can be changes to arguments in instructions, such as memory addresses or threshold values, or changes to OPCODES 502. Accordingly, the program memory 404 can be programmed to cause the CG accelerator 214 to perform methods other than or in addition to CG.

In some examples, the program memory 404 can be programmed to cause the vector APU 402 to cross-correlate two vectors. In some examples, an additional OPCODE 502 CROSSDOTPROD can be defined, as follows. If #D equals zero, then perform Equation 11, else perform Equation 12. #D is an argument in the CROSSDOTPROD instruction that can be zero or one. In some examples, #D can be another relatively small number, such as 2, 3, or 4.

M_{Z}(0)+jM_{Z+1}(0)=(M_{X}+jM_{X+1})^{H}×(M_{Y}+jM_{Y+1}) Equation 11

M_{Z}(nᵢ)+jM_{Z+1}(nᵢ)=(M_{X}+jM_{X+1})^{H}×(M_{Y,ni}+jM_{Y+1,ni}) Equation 12

Here, nᵢ=nᵢ₋₁+#D, and n₀ is initialized to zero when #D equals zero. M_{Y,ni} is a cyclically shifted memory, so that the first element read is bitwise shifted by nᵢ (to either the left or the right), the second element read is shifted from an unshifted starting position by nᵢ+1, and so on. Performing CROSSDOTPROD in a loop can be used to determine cross-correlation of two vectors, i.e., a value of nᵢ at which a resulting dot product—a result of Equation 11 or Equation 12—is a maximum (or a minimum). For example, cross-correlation can be performed using the following (pseudo-code) loop, in which N is the length of the M_{X} and M_{Y} vectors:

CROSSDOTPROD <#D=0>
i == 0
Loop Start : CROSSDOTPROD <#D=1>
i == i+1
GOTO Loop Start : if i < N
Pause

Modifications are possible in the described embodiments, and other embodiments are possible, within the scope of the claims.

In some examples, the wireless base station 100 is an analog front end (AFE) device.

In some examples, the CG determination block 206 is configurable to perform different variants of CG.

In some examples, the CG determination block 206 is configurable to use different numbers of iterations to perform CG.

In some examples, the processor 208 can control the vector APU 402 to perform methods other than or in addition to CG.

In some examples, the program memory 404 includes vector, memory, or process manipulation instructions other than or in addition to those described herein.

In some examples, vector memories 408 includes a different number of memories than in the example(s) described above. In some examples, a vector memory includes a different number of lines than in the example(s) described above.

In some example, vector length N can be configured by changing a value in a register.

In some example, the CG accelerator 214 uses a double precision format conforming to the IEEE-754 standard. In some examples, the CG accelerator 214 uses a floating point representation other than double precision. In some examples, the CG accelerator 214 uses a numerical representation other than a floating point representation. In some examples, the numerical representation used by the CG accelerator 214 is selected to satisfy system, precision, and dynamic range requirements. Dynamic range refers to the range between the smallest and the largest coefficients (e.g., smallest and largest magnitudes) that the CG accelerator 214 is able to effectively manipulate while retaining corresponding information. In some examples, the floating point or other numerical representation used by the CG accelerator 214 has a configurable precision.

In some examples, the output of the DPD corrector 112 is represented in the model used by the DPD estimator 116. In some examples, the output of the DPD corrector 112 is not represented in the model used by the DPD estimator 116.

In some examples, Hermitian matrix A is generated, and stored in the matrix memory 204, in fixed precision. In some such examples, Hermitian matrix A is converted to floating point (for example, to double precision) while being read from the matrix memory 204 and provided to the CG accelerator 214 for processing.

In some examples, the matrix memory 204 is configured to store a non-Hermitian complex matrix, and the CG accelerator 214 is configured to perform operations on the non-Hermitian complex matrix.

In some examples, two's complement arithmetic can be used.

In some examples, instruction level clock gating is used to save power when a specific one or ones of the arithmetic blocks 412 is not required by currently-executing instructions—accordingly, executions currently within a pipeline or scheduled for entry into a pipeline of the arithmetic blocks 412.

In some examples, the number of adder pipeline stages P_{A} is greater than or equal to two. In some example, the number of multiplier pipeline stages P_{M} is greater than or equal to two.

In some examples, the number of adder pipeline stages P_{A} equals one. In some examples, the number of multiplier pipeline stages P_{M} equals one.

In some examples, a delay circuit with an enable, or a different type of circuit to provide a value received at an input of the circuit at the output of the circuit one or more clock cycles after receipt, is used instead of the hold block 808. In some examples, the hold block 808 can be viewed as an example of a latch or a delay circuit with an enable.

In some examples, the complex multiplier 603 includes more multipliers or adders. In some examples, the complex multiplier 603 includes fewer multipliers or adders.

In some examples, execution of the CG method includes storing a solution that gives absolute minima for the residue is stored across iterations. That is, a solution xᵢ is stored that corresponds to the smallest rᵢ^{H}×rᵢ produced by an iteration of the CG method. In some examples, this stored solution is used to initialize x in subsequent iterations of the CG method.

In some examples, the number of dummy entries to be added to M memories at the end of a row of an upper triangle of an Hermitian matrix, to enable M-way parallelization of an operation executed by the CG accelerator 214, is given by Equation 13, where R is an integer, R and M are co-prime numbers, and R<M:

(LEN+DUM)mod M=(R+1)mod M Equation 13

In some examples, the number of dummy entries to be added to M memories at the end of a row of a lower triangle of an Hermitian matrix, to enable M-way parallelization of an operation executed by the CG accelerator 214, is given by Equation 14, where R is an integer, R and M are co-prime numbers, and R<M:

(LEN+DUM)mod M=R mod M Equation 14

In some examples, dummy entries can be added at the beginning of a row instead of at the end of a row. In some such examples, the number of dummy entries to be added to M memories at the beginning of a row of an upper triangle of an Hermitian matrix, to enable M-way parallelization of an operation executed by the CG accelerator 214, is given by Equation 15, where R is an integer, R and M are co-prime numbers, and R<M:

(LEN+DUM)mod M=R mod M Equation 15

In some examples, dummy entries can be added at the beginning of a row instead of at the end of a row. In some such examples, the number of dummy entries to be added to M memories at the beginning of a row of a lower triangle of an Hermitian matrix, to enable M-way parallelization of an operation executed by the CG accelerator 214, is given by Equation 16:

(LEN+DUM)mod M=(R+1)mod M Equation 16

In some examples, the zero selectably provided by one or more of the first, second, and/or third multiplexers 802, 804, and/or 806, is instead some other null value that will not affect a sum provided by adder-1 612 (this also applies to the second adder 614 and corresponding multiplexers).

In some examples, padding of an Hermitian matrix as stored in memory using dummy entries enables parallel access to M consecutive entries in a same row and different columns of the Hermitian matrix. In some examples, this can be used to implement M-way parallelized vector arithmetic.

In some examples, a number M real part block 618/complex part block 620 pairs with appropriate memory padding enables M-way parallelization, where M is an integer greater than or equal to two. In some examples, a number M real part block 618/complex part block 620 pairs with appropriate memory padding enables m-way parallelization, where m is an integer factor of M and is greater than or equal to two, so that k×m=M for an integer k.

In some examples, a number L arithmetic blocks and M matrix memories, with appropriate memory padding, enables up to M-way parallelization, where L and M are integers greater than or equal to two. An entry in a matrix memory stores one real or complex value, corresponding to real or complex arithmetic to be performed on the stored matrix. An arithmetic block includes two multipliers and an adder for complex vector arithmetic, or an arithmetic block includes a multiplier and an adder for real vector arithmetic. In such examples, a×M=L, k×m=M, k×1=L, and a×m=1, where k, l, and m are integers, a=1 for real vector arithmetic, and a=2 for complex vector arithmetic. (To clarify, the integer 1 is lower case L.) In other words, M-way parallelization of complex vector arithmetic uses twice as many arithmetic blocks as M-way parallelization of real vector arithmetic. Also, a DPD estimator 116 using L arithmetic blocks and M padded matrix memories to enable M-way parallelization can use 1 arithmetic blocks and m padded matrix memories to enable m-way parallelization, where l and m are factors of L and M, respectively.

The functional blocks described above may be implemented using one or more of the following: a processor, a microcomputer, a microcontroller, digital circuitry (such as logic circuitry), a state machine, analog circuitry, memory and/or software.

The term “couple” is used throughout the specification. The term may cover connections, communications, or signal paths that enable a functional relationship consistent with this description. For example, if device A provides a signal to control device B to perform an action, in a first example device A is coupled to device B, or in a second example device A is coupled to device B through intervening component C if intervening component C does not substantially alter the functional relationship between device A and device B such that device B is controlled by device A via the control signal provided by device A.

In this description, the term “and/or” (when used in a form such as A, B and/or C) refers to any combination or subset of A, B, C, such as: (a) A alone; (b) B alone; (c) C alone; (d) A with B; (e) A with C; (f) B with C; and (g) A with B and with C. Also, as used herein, the phrase “at least one of A or B” (or “at least one of A and B”) refers to implementations including any of: (a) at least one A; (b) at least one B; and (c) at least one A and at least one B.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin”, “ball” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Unless otherwise stated, “about,” “approximately,” or “substantially” preceding a value means +/−10 percent of the stated value, or, if the value is zero, a reasonable range of values around zero. Modifications are possible in the described examples, and other examples are possible within the scope of the claims.

What is claimed is:

1. An integrated circuit comprising:
an output terminal adapted to couple to an input of a power amplifier;
a feedback terminal adapted to couple to an output of the power amplifier;
a data terminal adapted to receive a data stream;
a digital pre-distortion (DPD) circuit including:
a capture circuit including a first input coupled to the data terminal, a second input coupled to the feedback terminal, and an output;
a DPD estimator including an input coupled to the capture circuit output, and an output, the DPD estimator including:
an instruction memory configured to store multiple instructions;
a vector arithmetic processing unit (APU) coupled to the instruction memory, including:
multiple vector memories;
multiple vector arithmetic blocks, including multiple vector addition blocks and multiple vector multiplication blocks; and
an instruction decode block configured to cause the vector APU to perform complex domain vector arithmetic on vectors stored in the vector memories in response to the instructions; and
a DPD corrector including a first input coupled to the data terminal, a second input coupled to the output of the DPD estimator, and an output coupled to the output terminal.

2. The integrated circuit of claim 1, wherein the instruction decode block is configured to decode instructions specifying one or more of: multiplication of a complex vector stored in the vector memories by a complex matrix stored in a memory external to the vector APU, a dot product of two complex vectors stored in the vector memories, a complex vector stored in the external memory plus a scalar stored in a register memory of the vector APU multiplied by a complex vector stored in the vector memories, or a complex vector stored in the vector memories plus a scalar stored in a register memory of the vector APU multiplied by a complex vector stored in the vector memories.

3. The integrated circuit of claim 1,
further including a matrix memory external to the vector APU and configured to store a complex matrix;
wherein the instruction decode block is configured to decode an instruction that specifies reading of the complex matrix from the matrix memory, and multiplication of the complex matrix by a complex vector stored in the vector memories.

4. The integrated circuit of claim 1, further including a sequencer configured to select instructions from the instruction memory in an order and to pass the instructions to the instruction decode block.

5. The integrated circuit of claim 1, wherein different pairs of the vector memories are configured to store real parts and imaginary parts of different complex vectors.

6. An integrated circuit comprising:
a memory configured to store multiple vectors; and
multiple arithmetic blocks coupled to the memory, ones of the arithmetic blocks including:
a multiplier including first and second inputs and an output;
an adder including first and second inputs and an output, the adder having a number P_{A} pipeline stages, where P_{A}≥2; and
a delay circuit including an input coupled to the output of the adder, and an output;
wherein the first input of the adder is selectably coupled to one of: the output of the multiplier, the output of the delay circuit, or a null value; and
wherein the second input of the adder is selectably coupled to one of: the output of the adder or a null value.

7. The integrated circuit of claim 6,
further including:
M matrix memories configured to store a matrix; and
a clock configured to provide a clock signal;
wherein the integrated circuit includes L arithmetic blocks, where L is an integer, L=a×M, a=1 for real vector operations, and a=2 for complex vector operations; and
wherein the arithmetic blocks are configured to process M vector operations in parallel, and the M matrix memories are configured so that M elements of the matrix corresponding to the M vector operations can be read in parallel in a single cycle of the clock signal.

8. The integrated circuit of claim 6, wherein each of the P_{A} pipeline stages is configured to process a separate partial accumulation including new input values selectably receivable from the first input of the adder and feedback values selectably receivable from the first and second inputs of the adder.

9. The integrated circuit of claim 6,
wherein the memory is configured to store multiple complex vectors;
wherein the multiplier is a first multiplier, and ones of the arithmetic blocks include a second multiplier including first and second inputs and an output;
wherein the adder includes a third input that is selectably coupled to one of: the output of the second multiplier or the null value.

10. The integrated circuit of claim 9,
wherein ones of the arithmetic blocks are real part blocks configured to produce a real part of the output, and ones of the arithmetic blocks are imaginary part blocks configured to produce an imaginary part of the output;
wherein, in ones of the real part blocks, a first one of the first multiplier or the second multiplier is configured to receive a real part of a first vector and a real part of a second vector, and a second one of the first multiplier or the second multiplier is configured to receive an imaginary part of the first vector and an imaginary part of the second vector; and
wherein, in ones of the imaginary part blocks, a first one of the first multiplier or the second multiplier is configured to receive the real part of a first vector and the imaginary part of the second vector, and a second one of the first multiplier or the second multiplier is configured to receive the imaginary part of the first vector and the real part of the second vector.

11. The integrated circuit of claim 10,
wherein the arithmetic blocks include M real part blocks and M imaginary part blocks; and
wherein the integrated circuit is configured to perform vector operations on M pairs of vectors in parallel.

12. The integrated circuit of claim 9, wherein each of the P_{A} pipeline stages is configured to process a separate partial accumulation including new input values selectably receivable from the first and third inputs of the adder and feedback values selectably receivable from the first and second inputs of the adder.

13. The integrated circuit of claim 6,
further including a clock configured to provide a clock signal;
wherein each of the pipeline stages is configured to, within one clock cycle of the clock signal, provide an output in response to an input of the respective pipeline stage.

14. The integrated circuit of claim 6,
wherein the adder is configured to add a sequence of values received from the multiplier by maintaining a separate partial accumulation within each of the P_{A} pipeline stages of the adder during a first phase; and
wherein the first phase ends, and a second phase begins, after the adder receives a last value from the multiplier; and
wherein the adder is configured to add the P_{A} partial accumulations together during the second phase to generate a result.

15. The integrated circuit of claim 6,
further including a first multiplexer and a second multiplexer;
wherein the selective coupling of the first input of the adder is performed by the first multiplexer; and
wherein the selective coupling of the second input of the adder is performed by the second multiplexer.

16. The integrated circuit of claim 6, wherein ones of the arithmetic blocks are configured to perform a vector multiplication operation on two vectors in O(N) time, wherein N is the length of each of the two vectors.

17. An integrated circuit comprising:
a clock configured to provide a clock signal;
a vector arithmetic processing unit (vector APU); and
a number M matrix memories coupled to the vector APU;
wherein a modified Hermitian matrix refers to an upper triangle or lower triangle of the Hermitian matrix, such that, where R is an integer, R and M are co-prime, and R<M, one of:
at the end of each row or row portion of the upper triangle of the Hermitian matrix having a number LEN elements, a number DUM dummy elements are appended, so that (DUM+LEN) modulo M=(R+1) modulo M;
at the end of each row or row portion of the lower triangle of the Hermitian matrix having LEN elements, the number DUM dummy elements are appended, so that (DUM+LEN) modulo M=R modulo M;
at the beginning of each row or row portion of the upper triangle of the Hermitian matrix, the number DUM dummy elements are prepended, so that (DUM+LEN) modulo M=R modulo M; or
at the beginning of each row or row portion of the lower triangle of the Hermitian matrix, the number DUM dummy elements are prepended, so that (DUM+LEN) modulo M=(R+1) modulo M; and
wherein the matrix memories are configured to store the modified Hermitian matrix sequentially by increasing column index within a row, then by increasing row index, so that sequentially successively indexed elements of the modified Hermitian matrix are stored within sequentially successively indexed, modulo M, ones of the matrix memories.

18. The integrated circuit of claim 17, wherein the vector APU is configured to cause M non-dummy elements of the modified Hermitian matrix to be read in parallel from the M matrix memories on successive cycles of the clock signal.

19. The integrated circuit of claim 18, wherein the vector APU is configured to use the read, non-dummy elements of the modified Hermitian matrix to perform a number M vector arithmetic operations in parallel.

20. The integrated circuit of claim 17,
wherein the vector APU includes an adder that has P_{A} pipeline stages; and
wherein the adder is configured to perform an addition operation in P_{A} cycles of the clock signal.
